(19) United States
(12) Patent Application Publication
(10) Pub. No.: US 2013/0200386 A1
(43) Pub. Date: Aug. 8, 2013

(54) CRYSTALLIZATION OF MULTI-LAYERED AMORPHOUS FILMS

(71) Applicants: Douglas Arthur Hutchings, Elkins, AR (US); Seth Daniel Shumate, Fayetteville, AR (US); Hameed Naseem, Fayetteville, AR (US); Khalil Hashim Sharif, Fayetteville, AR (US); Hafeezuddin Mohammed, Fayetteville, AR (US)

(72) Inventors: Douglas Arthur Hutchings, Elkins, AR (US); Seth Daniel Shumate, Fayetteville, AR (US); Hameed Naseem, Fayetteville, AR (US); Khalil Hashim Sharif, Fayetteville, AR (US); Hafeezuddin Mohammed, Fayetteville, AR (US)

(73) Assignees: SILICON SOLAR SOLUTIONS, LLC, Fayetteville, AR (US); BOARD OF TRUSTEES OF THE UNIVERSITY OF ARKANSAS, Little Rock, AR (US)

(21) Appl. No.: 13/702,930

(22) PCT Filed: Jun. 8, 2011
(86) PCT No.: PCT/US2011/039574

§ 371 Date: Feb. 3, 2013

Related U.S. Application Data
(60) Provisional application No. 61/352,681, filed on Jun. 8, 2010.

(51) Int. Cl. H01L 31/18

(52) U.S. Cl. CPC H01L 31/182
USPC 257/75; 438/97; 118/719; 204/298.09

(57) ABSTRACT

In one aspect, crystallization of multiple layers of amorphous materials is disclosed. In one embodiment, multiple layers of amorphous materials such as amorphous silicon, silicon carbide, and/or germanium are deposited using deposition methods such as PECVD or sputtering. A layer of metal such as aluminum is deposited on the surface of the deposited amorphous materials using sputtering or evaporation, and the structure is annealed in a hydrogen environment. The structure is contained on a semiconductor substrate, glass, a flexible metal/organic film, or other type of substrate.

This application is being filed as PCT International Patent application in the names of Board of Trustees of the University of Arkansas, and U.S. national corporation, and Silicon Solar Solutions, LLC, a U.S. national corporations, Applicants for all countries except the U.S., and Douglas A. Hutchings, a U.S. citizen; Seth D. Shumate, a U.S. citizen; Hameed Naseem, a U.S. citizen; and Khalil H. Sharif, a U.S. citizen, Applicants for the designation of the U.S. only, on Jun. 8, 2011.

### CROSS-REFERENCE TO RELATED PATENT APPLICATION

This application claims the benefit, pursuant to 35 U.S.C. §119(e), of provisional U.S. Patent Application Ser. No. 61/352,681, filed Jun. 8, 2010, entitled “Method of Metal Induced Crystallization of Amorphous Silicon and Method of Doping” by Douglas Arthur Hutchings et al., the disclosure for which is herein incorporated by reference in its entirety.

Some references, which may include patents, patent applications and various publications, are cited and discussed in the description of this invention. The citation and/or discussion of such references is provided merely to clarify the description of the present invention and is not an admission that any such reference is “prior art” to the invention described herein. All references cited and discussed in this specification are incorporated herein by reference in their entireties and to the same extent as if each reference was individually incorporated by reference. In terms of notation, hereinafter, “[n]” represents the nth reference cited in the reference list. For example, [4] represents the 4th reference cited in the reference list, namely, M. Zou et al., “Fabrication of large grain polycrystalline silicon film by nano aluminum-induced crystallization of amorphous silicon,” U.S. Pat. No. 7,687,334 B2, Mar. 30, 2010.

### STATEMENT OF FEDERALLY-SPONSORED RESEARCH

The present invention was made with Government support awarded by the National Science Foundation SBIR Phase 1 award number 1047296. The United States Government has certain rights to this invention pursuant to this grant.

### FIELD OF THE INVENTION

The present invention generally relates to methods and apparatus for forming a polycrystalline film.

### BACKGROUND OF THE INVENTION

In a single hour, the sun delivers more energy to the earth's surface than the human population uses in an entire year. In order for solar energy to be effectively converted, photovoltaic (PV) technologies need to provide efficient energy conversion ratios. Further, in order to compete with the existing markets for non-renewable energy sources, solar conversion needs to be accomplished in a cost-effective manner. The Department of Energy (DOE) is seeking technologies to make photovoltaics and solar energy more competitive on the open market. Thin film solar cells can circumvent the costly silicon waste associated with wafer based devices. In their solar technology roadmap, the DOE sets out several key issues that should be addressed before thin film silicon can gain effective market share. The DOE highlights a need for a mechanism to produce large grains and well passivated grain boundaries [2].

Thin film silicon solar cells contain layers of deposited silicon and are typically less than 10 μm in thickness. The crystallinity of these silicon layers ranges from fully amorphous (a-Si:H) to a mixture of amorphous and crystalline (micro/nanocrystalline silicon) to fully crystallized polysilicon. Amorphous silicon solar cells are subject to light induced degradation known as the Staebler-Wronski effect, which limits conversion efficiency by 15-30% within the first few months of illumination. Polysilicon takes advantage of some known benefits of wafer based silicon cells: high conversion efficiencies, abundance of materials, and proven long-term stability [1].

Several conventional processes exist for crystallizing hydrogenated amorphous silicon (a-Si:H). One approach that uses plasma-enhanced chemical vapor deposition (PECVD) of a-Si:H requires a solid phase crystallization step which takes 20 hours to achieve relatively small grain sizes, and temperatures of 500-700° C. are required. Metal-induced crystallization (MIC) provides an avenue for producing thin film silicon with larger grain sizes. However, many existing metal-induced crystallization processes require multiple deposition steps and even higher temperatures than those associated with wafer-based thermal diffusion, sometimes in excess of 1000° C.

Therefore, heretofore unaddressed needs still exist in the art to address the aforementioned deficiencies and inadequacies.

### SUMMARY OF THE INVENTION

In one aspect, the present invention relates to crystallization of multiple layers of amorphous material while controlling the resultant doping density of each layer. In one embodiment, multiple layers of amorphous materials such as amorphous silicon, silicon carbide, and/or germanium are deposited using deposition methods such as PECVD, LPCVD, or sputtering. A layer of metal such as aluminum is deposited on the surface of the deposited amorphous materials using sputtering or evaporation, followed by annealing the structure in a hydrogen atmosphere. The structure is contained on a semiconductor substrate, glass, a flexible metal/organic film, or other type of substrate.

In another aspect, the present invention relates to a method for forming a polycrystalline film on a substrate. In one embodiment, the method includes the step of forming an amorphous film having a plurality of layers on a substrate, where the plurality of layers include at least a first layer formed in a first environment and a second layer formed in a second, different environment. The method further includes the steps of forming a metal layer on the amorphous film to form a structure having the substrate, the metal layer, and the amorphous film positioned between the substrate and the metal layer, and annealing the structure at an annealing temperature for a predetermined period of time to at least partially crystallize the plurality of layers of the amorphous film simultaneously.

In one embodiment, the multiple layers of the amorphous film are formed in one continuous step of sputtering or chemical vapor deposition, where the first environment is dynamically changed to the second environment during the continuous step. The first environment and second environment include precursor gases for pre-crystallization, for example diborane in the first environment and phosphine in the second environment. The amorphous film includes amorphous materials such as amorphous silicon, germanium, and/or silicon carbide. In one embodiment, the amorphous film is formed to have a thickness within a range from about 0.1 μm to about 40 μm and is formed at a pressure of about 10⁻⁶ torr.

In one embodiment, the metal layer is formed by sputtering or thermal evaporation to have a thickness that is about the same as the thickness of the amorphous film, for example in a range from about 5 nm to about 300 nm. In one embodiment, the metal layer is formed at a pressure of about 10⁻⁸ torr.

In one embodiment, the step of annealing the structure includes at least one of raising, maintaining, and lowering the annealing temperature during the predetermined period of time, where the annealing temperature is within a range from about 150° C. to about 550° C. The structure is annealed in an annealing environment that includes hydrogen or argon. In one embodiment, the first environment and the second environment are adapted such that the amorphous film is formed to be at least partially hydrogenated and the predetermined period of time is within a range from about 15 minutes to about 20 hours.

In one embodiment, the substrate is heated to about 200° C.

In one embodiment, the step of forming an amorphous film further includes forming a third layer in a third environment that is different from the first environment and the second environment. In one embodiment, the amorphous film having the first layer, second layer, and third layer is formed in one continuous step, where the first environment is dynamically changed to the second environment and the second environment is dynamically changed to the third environment during the continuous forming step. The first environment, second environment, and third environment include precursor gases for pre-crystallization, for example diborane, phosphine, and silane, respectively.

In yet another aspect, the present invention relates to a polycrystalline film formed by a method that includes the steps of forming an amorphous film having a plurality of layers on a substrate, the plurality of layers including at least a first layer formed in a first environment and a second layer formed in a second, different environment. The method further includes the step of forming a metal layer on the amorphous film to form a structure having the substrate, the metal layer, and the amorphous film positioned between the substrate and the metal layer, and the step of annealing the structure at an annealing temperature for a predetermined period of time to at least partially crystallize the plurality of layers of the amorphous film simultaneously.

In yet another aspect, the present invention relates to a method for forming a polycrystalline silicon film on a substrate. In one embodiment, the method includes the step of forming an amorphous silicon film having a plurality of layers on a substrate, the plurality of layers including at least a first layer formed in a first environment and a second layer formed in a second, different environment, and forming an aluminum layer on the amorphous silicon film to form a structure having the substrate, the aluminum layer, and the amorphous silicon film positioned between the substrate and the aluminum layer. The method further includes the step of annealing the structure at an annealing temperature for a predetermined period of time to at least partially crystallize the plurality of layers of the amorphous silicon film simultaneously.

In one embodiment, the first layer and second layer are formed in one continuous step, and the first environment and second environment include precursor gases for pre-crystallization, for example diborane and phosphine, respectively. The first environment is dynamically changed to the second environment during the continuous forming step.

In one embodiment, the amorphous silicon film is formed to have a thickness within a range from about 0.1 μm to about 40 μm. In one embodiment, the amorphous silicon film is formed by sputtering or chemical vapor deposition such as PECVD at a pressure of about 10⁻⁶ torr.

In one embodiment, the aluminum layer is formed by sputtering or thermal evaporation, such as by sputtering at a pressure of about 10⁻⁸ torr, with a thickness in a range from about 5 nm to about 300 nm. In one embodiment, the aluminum layer is formed with a thickness that is about the same as the thickness of the amorphous silicon film.

In one embodiment, the step of annealing the structure includes at least one of raising, maintaining, and lowering the annealing temperature during the predetermined period of time. In one embodiment, the annealing temperature is within a range from about 150° C. to about 550° C. and the structure is annealed in an annealing environment that includes hydrogen or argon for a predetermined period of time that is within a range from about 15 minutes to about 20 hours. In one embodiment, the first environment and the second environment are adapted such that the amorphous silicon film is formed at least partially of hydrogenated amorphous silicon.

In one embodiment, the substrate is heated to about 200° C.

In one embodiment, the step of forming an amorphous silicon film further includes forming a third layer in a third environment that is different from the first environment and the second environment, where the first layer, second layer, and third layer are formed in one continuous step and the first environment is dynamically changed to the second environment and the second environment is dynamically changed to the third environment during the continuous forming step. In one embodiment, the third environment includes a precursor gas for pre-crystallization, for example silane.

In yet another aspect, the present invention relates to a polycrystalline film formed by a method that includes the step of forming an amorphous film having a plurality of layers on a substrate. In one embodiment, the plurality of layers include at least a first layer formed in a first environment and a second layer formed in a second, different environment. The method further includes the step of forming a metal layer on the amorphous film to form a structure having the substrate, the metal layer, and the amorphous film positioned between the substrate and the metal layer, as well as the step of annealing the structure at an annealing temperature for a predetermined period of time to at least partially crystallize the plurality of layers of the amorphous film simultaneously.

In yet another aspect, the present invention relates to an apparatus for forming a polycrystalline film. In one embodiment, the apparatus includes a film forming system configured to form an amorphous film having a plurality of layers on a substrate, where the plurality of layers include at least a first layer formed in a first environment and a second layer formed in a second, different environment. The apparatus also includes a metal layer forming system configured to form a metal layer on the amorphous film to form a structure having the substrate, the metal layer, and the amorphous film positioned between the substrate and the metal layer. The system further includes an annealing means configured to anneal the structure at an annealing temperature for a predetermined period of time to at least partially crystallize the plurality of layers of the amorphous film simultaneously.

In one embodiment, the first layer and second layer of the amorphous film are formed in one continuous step, where the first environment is dynamically changed to the second environment during the continuous forming step. The first environment and the second environment include precursor gases for pre-crystallization, for example diborane and phosphine, respectively.

In one embodiment, the film forming system, metal layer forming system, and annealing means are configured such that the functions of forming the amorphous film, forming the metal layer, and annealing the structure are performed as a continuous process and in a sequential order.

In one embodiment, the film forming system is further configured to form the amorphous film to include a third layer in a third environment that is different from the first environment and the second environment, where the first environment is dynamically changed to the second environment and the second environment is dynamically changed to the third environment while the amorphous silicon film is being formed. In one embodiment, the third environment includes a precursor gas for pre-crystallization, for example silane.

In one embodiment, the film forming system includes one of a chemical vapor deposition system, electron cyclotron resonance system, electron beam physical vapor deposition system, and sputtering system. In one embodiment, the film forming system includes one of a plasma-enhanced chemical vapor deposition system (PECVD), low-pressure chemical vapor deposition (LPCVD) system, and hot wire chemical vapor deposition system.

In one embodiment, the amorphous film includes at least one of amorphous silicon, germanium, and silicon carbide and has a thickness within a range from about 0.1 μm to about 40 μm. In one embodiment, the film forming system is configured to form the amorphous film at a pressure of about 10⁻⁶ torr.

In one embodiment, the metal layer forming system includes a sputtering system or a thermal evaporation system configured to form an aluminum layer having a thickness in a range from about 5 nm to about 300 nm, at a pressure of about 10⁻⁸ torr. In one embodiment, the metal layer is formed with a thickness that is about the same as the thickness of the amorphous film.

In one embodiment, the annealing means is configured to selectively cause the annealing temperature to be at least one of raised, maintained, and lowered during a predetermined period of time that is within a range from about 15 minutes to about 20 hours. The annealing temperature is within a range from about 150° C. to about 550° C. and the structure is annealed in an environment that includes hydrogen or argon. In one embodiment, the first environment and the second environment are adapted such that the amorphous film is formed to be at least partially hydrogenated.

In one embodiment, the substrate is heated to about 200° C.

These and other aspects of the present invention will become apparent from the following description of the preferred embodiment taken in conjunction with the following drawings and their captions, although variations and modifications therein may be affected without departing from the spirit and scope of the novel concepts of the disclosure.

### BRIEF DESCRIPTION OF THE DRAWINGS

The accompanying drawings illustrate one or more embodiments of the invention and, together with the written description, serve to explain the principles of the invention. Wherever possible, the same reference numbers are used throughout the drawings to refer to the same or like elements of an embodiment, and wherein:

FIG. 1 schematically shows a cross-sectional side view of a polycrystalline film according to one embodiment of the present invention;

FIG. 2 illustrates metal-induced crystallization (MIC) for producing a doped polycrystalline silicon film, according to one embodiment of the present invention, where (A) shows a nucleation phase, (B) shows a growth phase, and (C) shows a coalescence phase;

FIG. 3 schematically shows deposition methods and precursor gas environments for forming pre-crystallization amorphous film layers and a metal layer on the amorphous film layers, according to one embodiment of the present invention;

FIG. 4 schematically shows an apparatus for forming a polycrystalline film, according to one or more embodiments of the present invention; and

FIG. 5 is a flow chart illustrating operational steps of a method for forming a polycrystalline film, according to one embodiment of the present invention.

### DEFINITIONS

The terms used in this specification generally have their ordinary meanings in the art, within the context of the invention, and in the specific context where each term is used.

Certain terms that are used to describe the invention are discussed below, or elsewhere in the specification, to provide additional guidance to the practitioner in describing the apparatus and methods of the invention and how to make and use them. For convenience, certain terms may be highlighted, for example using italics and/or quotation marks. The use of highlighting has no influence on the scope and meaning of a term; the scope and meaning of a term is the same, in the same context, whether or not it is highlighted. It will be appreciated that the same thing can be said in more than one way. Consequently, alternative language and synonyms may be used for any one or more of the terms discussed herein, nor is any special significance to be placed upon whether or not a term is elaborated or discussed herein. Synonyms for certain terms are provided. A recital of one or more synonyms does not exclude the use of other synonyms. The use of examples anywhere in this specification, including examples of any terms discussed herein, is illustrative only, and in no way limits the scope and meaning of the invention or of any exemplified term. Likewise, the invention is not limited to various embodiments given in this specification. Furthermore, subtitles may be used to help a reader of the specification to read through the specification, which the usage of subtitles, however, has no influence on the scope of the invention.

As used herein, “about” or “approximately” shall generally mean within 20 percent, preferably within 10 percent, and more preferably within 5 percent of a given value or range. Numerical quantities given herein are approximate, meaning that the term “about” or “approximately” can be inferred if not expressly stated.

As used herein, “polysilicon” is synonymous with “polycrystalline silicon.”

### Overview of the Invention

The present invention is more particularly described in the following examples that are intended as illustrative only since numerous modifications and variations therein will be apparent to those skilled in the art. Various embodiments of the invention are now described in detail. Referring to the drawings, like numbers indicate like components throughout the views. As used in the description herein and throughout the claims that follow, the meaning of “a”, “an”, and “the” includes plural reference unless the context clearly dictates otherwise. Also, as used in the description herein and throughout the claims that follow, the meaning of “in” includes “in” and “on” unless the context clearly dictates otherwise.

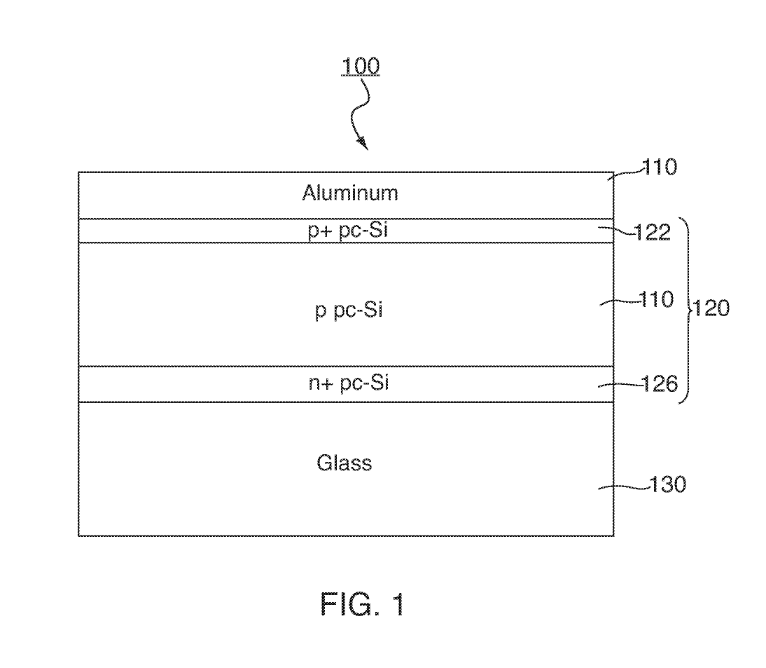

The description will be made as to the embodiments of the present invention in conjunction with the accompanying drawings in FIGS. 1-4.

FIG. 1 shows a cross-sectional view of a polycrystalline film, according to one embodiment of the present invention. As shown, an amorphous film 120 with a plurality of layers 122, 124, 126 is formed on a substrate 130. In one embodiment, the layers 122, 124, 126 are formed in one continuous step. The first layer 122 is formed in a first environment, the second layer 126 is formed in a second, different environment, and the third layer 124 is formed in third environment that is different from the first environment and the second environment. A metal layer 110 is formed on the amorphous film 120 to form a structure having the substrate 130, the metal layer 110, and the amorphous film 120 positioned between the substrate 130 and the metal layer 110. The structure is annealed at an annealing temperature for a predetermined period of time to at least partially crystallize the plurality of layers 122, 124, 126 of the amorphous film 120 simultaneously.

More particularly, FIG. 1 provides a cross-sectional view of a large grain polysilicon thin film 100, according to one embodiment of the present invention. As shown, an amorphous silicon film 120 is formed on the glass substrate 130, and an aluminum layer 110 is formed on the amorphous silicon film 120. As shown, the amorphous silicon film 120 includes a p+ polycrystalline silicon (pc-Si) layer 122, a p-type pc-Si layer 124, and an n+ pc-Si layer 126, and positioned between the aluminum layer 110 and the glass substrate 130.

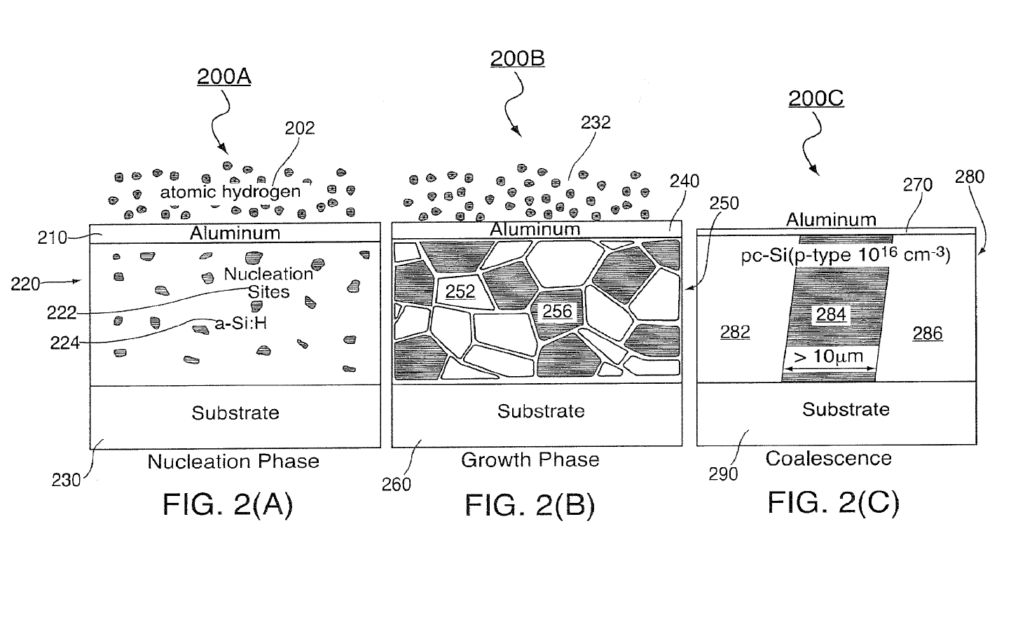

FIG. 2 illustrates a cross-sectional view of three phases of metal-induced crystallization (MIC) for producing a doped polycrystalline film, according to one embodiment of the invention, where (A) shows the nucleation phase 200A, (B) shows the growth phase 200B, and (C) shows the coalescence phase 200C. It should be noted that the region 220 in the nucleation phase shown in FIG. 2A corresponds to the region 250 in the growth phase shown in FIG. 2B and the region 280 in the coalescence phase shown in FIG. 2C. Likewise, the metal layer 210 shown in the nucleation phase of FIG. 2A corresponds to the metal layer 240 shown in the growth phase of FIG. 2B and the metal layer 270 shown in the coalescence phase of FIG. 2C. Further, the substrate 230 shown in the nucleation phase of FIG. 2A corresponds to the substrate 260 shown in the growth phase of FIG. 2B and the substrate 290 shown in the coalescence phase of FIG. 2C.

More particularly, FIG. 2 shows hydrogen-assisted top-down aluminum-induced crystallization (TAIC) for producing a polycrystalline silicon layer for thin film photovoltaic cells. In hydrogen-assisted TAIC, atomic hydrogen 202 (FIG. 2A), 232 (FIG. 2B) enhances the diffusion of aluminum 210, 240, 270 to allow for even distribution of nucleation sites 222. In the nucleation phase 200A shown in FIG. 2A, a silicon film 220 is positioned between the aluminum layer 210 and a substrate 230. The silicon film 220 includes nucleation sites 222 and a-Si:H 224. As shown by the growth phase 200B in FIG. 2B together with the coalescence phase 200C in FIG. 2C, crystals 252 and 256 grow to meet one another and then coalesce to form single large grains 282, 284, and 286 with doping densities and crystallization depths controlled for the optimal properties needed by thin film silicon devices. Aluminum atoms form bonds with hydrogen and diffuse throughout the >2 μm a-Si:H depth quickly and evenly. By annealing in hydrogen, a three-dimensional crystal coalescence event is achieved for any desired thickness.

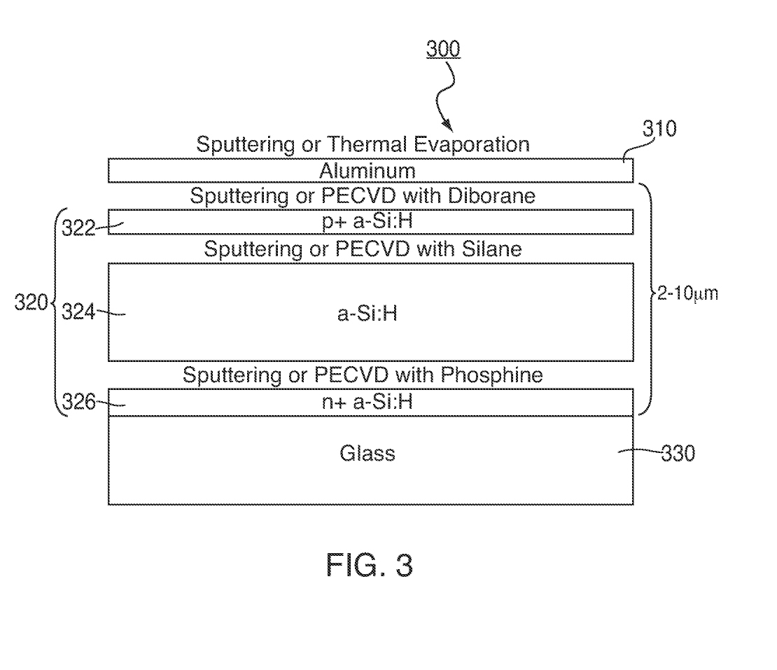

FIG. 3 schematically shows a cross-section of deposited layers and corresponding deposition methods and precursor gas environments for forming a polycrystalline film, collectively labeled 300, according to one embodiment of the present invention. More particularly, FIG. 3 shows an amorphous silicon film 320 with a thickness of 2-10 μm on a glass substrate 330. The amorphous silicon film 320 includes three layers: a first, p+ layer 322 formed by sputtering or PECVD in a first environment that includes diborane; a second, n+ layer 326 formed by sputtering or PECVD in a second environment that includes phosphine, and a third layer 324 positioned between the first layer 322 and the second layer 326, formed in a third environment that includes silane. In one embodiment, the three layers 322, 324, and 326 are formed in one continuous step of sputtering or PECVD. As shown, an aluminum layer 310 is formed on the amorphous silicon film 320 by sputtering or thermal evaporation.

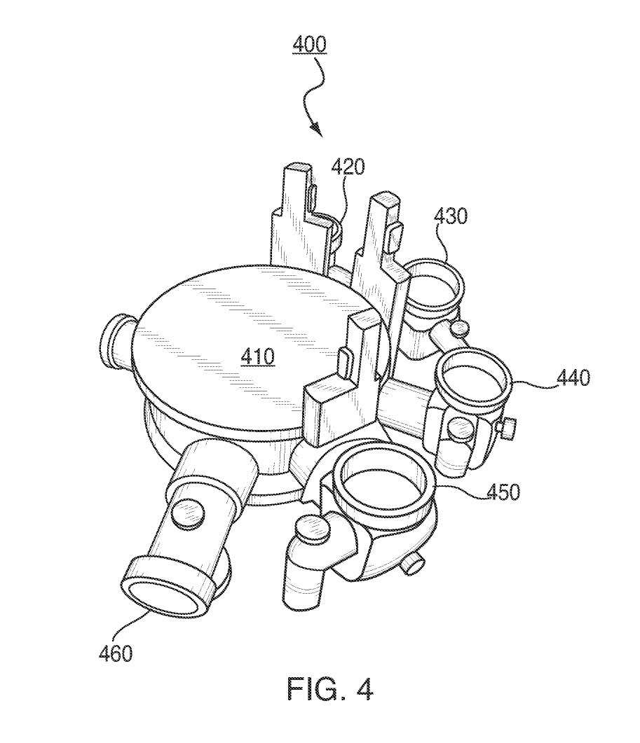

FIG. 4 schematically shows an apparatus 400 for forming a polycrystalline film, according to one or more embodiments of the present invention. More particularly, FIG. 4 shows a five-chambered thin film PECVD and DC Magnetron Sputtering tool 400. Samples up to 4″ square are loaded into an internal transfer zone (ITZ) 410 where a robotic arm picks up the substrate holder and delivers it to one of five main processing zones (MPZs) 420, 430, 440, 450, and 460. Processing zone 420 and processing zone 430 are PECVD chambers. Processing zone 450 is a sputtering chamber for a-Si:H, and processing zone 440 is a sputtering chamber for aluminum. Chambers 420, 430, 440, and 450 are separated from the ITZ 410 by gate valves and each pair has one turbo pump capable of ultra-high vacuum in the range of ˜10⁻⁸ Torr. An annealing chamber 460 connected to the ITZ 410 can be pumped down to ˜10⁻⁶ Torr.

It should be appreciated that one or more apparatuses other than the tool 400 shown in FIG. 4 may be used to perform one or more of the functions of forming the amorphous film, forming the metal layer, and/or annealing the structure. For example, in one alternative embodiment, an apparatus has the film forming system, metal layer forming system, and annealing means disposed in a selective arrangement and configured such that the functions of forming the amorphous film, forming the metal layer, and annealing the structure are performed as a continuous process and in a sequential order. For example, in one embodiment, processing chambers for forming the amorphous film, forming the metal layer, and annealing the structure are disposed in a linear or other type of sequential arrangement such that a polycrystalline film is produced by a continuous process that proceeds from one or more chambers for forming the amorphous silicon layer, then to one or more chambers for forming the metal layer, and then to one or more chambers for annealing the structure. In one embodiment, the chambers are disposed in a sequential arrangement to provide for a continuous, belt-driven process.

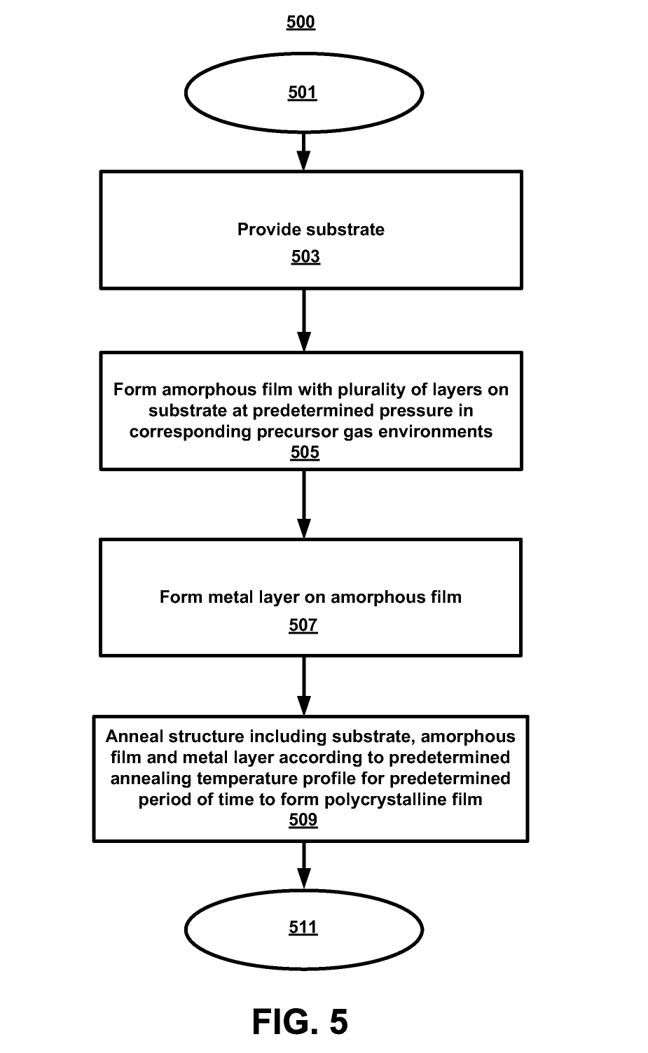

FIG. 5 is a flow chart illustrating operational steps of a method 500 for forming a polycrystalline film, according to one embodiment of the present invention. As shown, the operational steps begin at block 501 and proceed to step 503, where a substrate is provided. Next, at step 505 an amorphous film with a plurality of layers is formed on the substrate at a predetermined pressure, in an environment having one or more precursor gases. After step 505, operational flow proceeds to step 507, where a metal layer is formed on the amorphous film. Following step 507, at step 509 the structure having the substrate, the amorphous film formed on the substrate, and the metal layer formed on the amorphous film is annealed according to a predetermined annealing temperature profile and for a predetermined period of time to form a polycrystalline film. The operational steps of the method 500 end at block 511.

### IMPLEMENTATIONS AND EXAMPLES OF THE INVENTION

Without intent to limit the scope of the invention, exemplary systems and methods and their related results according to the embodiments of the present invention are given below. Note that titles or subtitles may be used in the examples for convenience of a reader, which in no way should limit the scope of the invention. Moreover, certain theories are proposed and disclosed herein; however, in no way they, whether they are right or wrong, should limit the scope of the invention so long as the invention is practiced according to the invention without regard for any particular theory or scheme of action.

### Example 1

According to various aspects, this Example relates to crystallizing multiple layers of hydrogenated amorphous silicon, with selective variations in doping profile, simultaneously. All of the active layers are deposited essentially in a single step. Hydrogen doping control is used to yield a desired impurity doping level in each layer. Top-down aluminum induced crystallization (TAIC) is implemented such that aluminum is able to freely associate with hydrogen near the surface before being locked into the crystal structure. The aluminum doping density depends on the temperature and amount of atomic hydrogen in the milieu during the annealing portion of TAIC.

As can be seen at least in part in the exemplary embodiments shown in FIGS. 1-3, around 2 micrometers of hydrogenated amorphous silicon (a-Si:H) is deposited on a substrate using PECVD, a substrate temperature of 200° C., and a pressure of 10⁻⁶ torr. During the deposition, precursor gases are changed from diborane to phosphine to result in an N+ and P+ layer of amorphous silicon. An approximately ˜300 nm thick aluminum layer is deposited using sputtering at a pressure of around 10⁻⁸ torr. The resulting structure is then annealed between 150-350° C. to at least partially crystallize the material in the presence of hydrogen.

### Example 2

This Example relates to metal induced crystallization (MIC) using aluminum in a top-down fashion (TAIC). Aluminum is a low level acceptor impurity and it is the third most abundant element in the earth's crust. During TAIC, aluminum atoms diffuse through and initiate crystallization of a-Si:H films at temperatures well below the eutectic temperatures. The eutectic temperature of aluminum and silicon is 577° C. TAIC can be used to crystallize a-Si:H at temperatures as low as 100° C. In performing TAIC, a thin layer of aluminum is deposited onto the surface of the a-Si:H layer, which has a native oxide layer that limits the diffusion of aluminum. This native oxide layer represents a relaxed manufacturing constraint because exposure to air is non-problematic. It limits the diffusion of the aluminum causing fewer initial nucleation sites. The result has been shown to produce very large grain polysilicon [4, 5, 6].

The a-Si:H layers can be fully crystallized in less than an hour. Li Cai, et al. showed that lower annealing temperatures resulted in larger grain sizes, and also that thinner aluminum layers actually increase grain sizes [6]. Both of these reductions from a manufacturing standpoint are quite appealing. For instance, to form the emitter layers of 4″ solar cells using TAIC, a manufacturer only needs the equivalent of one soda can tab, and instead of requiring many hours of temperatures in excess of 850° C. for thermal diffusion, a manufacturer needs less than 300° C. for less than an hour [4, 5].

### Crystallization Depth Control

Grain sizes throughout the active layer of thin film polysilicon cells should be greater than 10 μm [3, 8] because the defects at grain boundaries act as trapping, scattering, and recombination centers. Conventionally, large grain thin film solar cells have been achieved by starting with a large grain seed layer. The seed layer can be created either by re-annealing with lasers or with variants of MIC. MIC specifically with aluminum and nickel has been shown to create grains in excess of 90 μm [4, 9] for a-Si:H thicknesses of less than 200 nm, yielding high grain diameter/layer thickness aspect ratios. With effective light trapping techniques, the thickness of a thin film crystalline solar cell needs to be 2 μm [8]. Therefore the crystallization depth of TAIC should be controlled to achieve a process requiring the lowest processing time and temperature and to yield large grain sizes, for applications in fields of technology such as the creation of thin film polycrystalline solar cells. Among other advantages over conventional approaches, in one or more aspects, the present invention according to this Example provides for full crystallization of thick (>2 μm) amorphous silicon films using TAIC.

### Hydrogen Doping Control

According to aspects of the present invention disclosed in this Example, samples are annealed in an atomic hydrogen environment. A lighter doped (10¹⁶ cm⁻³) p-type base layer is created for a thin film solar cell that only requires a single step TAIC process. Since a hydrogenation step only affects the p+ doped layer and not the n+ emitter layer [12], doping density is tuned during the annealing step through controlling the temperature as well as the ambient hydrogen content. Hydrogen passivation of grain boundaries in multicrystalline solar cells has been found to increase overall conversion efficiencies [13]. Hydrogen passivation of intragrain defects and grain boundaries is necessary to optimize electrical characteristics of thin film polycrystalline solar cells [1], however this hydrogenation step generally occurs after deposition. By hydrogenating while annealing, an extra manufacturing step can be eliminated.

Atomic hydrogen increases the diffusivity of aluminum into a-Si:H, thereby enhancing the crystallization process of TAIC. Hydrogen has also been found to enhance the diffusivity of boron by a factor of two into SiO₂ [14]. Aluminum atoms form bonds with hydrogen and diffuse throughout the >2 μm a-Si:H quickly and evenly. By annealing in hydrogen, a three-dimensional crystal coalescence event is achievable for any desired thickness. In production, it is essential to maintain optimal grain sizes (>10 μm) while at the same time controlling the doping density and thickness of crystallization.

### Crystallization Depth

To determine TAIC crystallization depth, a process of deposition, annealing, and crystal quality measurements is performed. With regard to a-Si:H deposition, PECVD is used to deposit greater than 2 μm a-Si:H onto an n-type silicon wafer. N-type is chosen because the resulting crystallized film is p-type, creating a diode for evaluating the film's electronic qualities. Either thermal evaporation or sputtering is used to deposit aluminum film on the a-Si:H. Thicknesses start at 5 nm which is just above the threshold for crystallization [16]. Cai, et al. reported large grains (>50 μm) with reduced aluminum thickness as compared to 1 μm grains using greater amounts of aluminum with similar crystalline quality as determined through Raman spectroscopy [6]. TAIC allows for production of 60 μm grains by slowly ramping up the annealing temperature to 280° C. over a one hour period [4]. If this ramp time is increased to twenty hours for the same maximum temperature, grains were reported to be greater than 90 μm.

Grain boundaries as well as any surface defects within the grains can be visually inspected after chemical defect etching through optical and scanning electron microscopy (SEM). Crystallization depths are determined through cross-sectional TEM analysis including Selected Area Diffraction (SAD). The crystalline fraction of samples is determined through Raman spectroscopy [11, 17].

Aluminum distribution and active doping require distinct measurements. Secondary Ion Mass Spectroscopy (SIMS) is used to determine the aluminum concentration in the crystallized films. Not all of the aluminum will be electronically active, as some is in interstitial and substitutional sites. Aluminum concentrations as high as 3 at. % (SIMS) have been demonstrated for ˜10¹⁸ cm⁻³ carrier concentrations as determined by Hall measurements [16]. To determine the aluminum concentration, an Induced Coupled Plasma Atomic Absorption Spectrometer (ICP-AAS) is also utilized. These measurements are performed to monitor whether or not the doping profile reaches a target ˜10¹⁶ cm⁻³ range that is ideal for one embodiment of a solar cell collector layer as an effect of limiting aluminum thicknesses as discussed previously. Hydrogenation can be used for doping control and/or defect passivation.

With regard to diode characteristics, measurement of solar cell characteristics including dark and illuminated I-V characteristics are carried out, and depending on the output values of these measurements such as for open-circuit voltage (V_{oc} and short circuit current (I_{sc}), the conversion efficiency (η) and overall ‘photovoltaic’ quality of the test films can be determined.

The majority of the deposition occurs in the ultra-high vacuum PECVD/Sputtering cluster tool shown FIG. 4. More particularly, FIG. 4 illustrates a five-chambered thin film PECVD and DC Magnetron Sputtering tool 400. Samples up to 4″ square are loaded into an internal transfer zone (ITZ) 410 where a robotic arm picks up the substrate holder and delivers it to one of five main processing zones (MPZs) 420, 430, 440, 450, and 460. Processing zone 420 and processing zone 430 are plasma-enhanced chemical vapor deposition (PECVD) chambers. Processing zone 450 is a sputtering chamber for a-Si:H, and processing zone 440 is a sputtering chamber for aluminum. Chambers 420, 430, 440, and 450 are separated from the ITZ 410 by gate valves and each pair has one turbo pump capable of ultra-high vacuum in the range of ˜10⁻⁸ Torr. An annealing chamber 460 connected to the ITZ 410 can be pumped down to ˜10⁻⁶ Torr. The majority of the a-Si:H deposition takes place in PECVD chambers 420 and 430 where silane (SiH₄), phosphine (PH₃), and eventually diborane (B₂H₆) act as precursor gases to be decomposed into preferentially doped films.

### Hydrogen Doping Control

Annealing is carried out in a partial hydrogen environment, to control the doping of the collector layer to ˜10¹⁶ cm⁻³. Pankove, et al. found that 85% of surface boron dopants were passivated by hydrogen, meaning they were no longer electronically active impurities [18]. By TAIC, however, aluminum is able to freely associate with hydrogen near the surface before being locked into the crystal structure. This also enhances the diffusivity of aluminum [14]. Aluminum dopant neutralization depends on the temperature and amount of atomic hydrogen in the milieu during the annealing portion of TAIC. These parameters can be varied to maintain the film quality obtained during the crystal quality and depth measurement processes.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

### LIST OF REFERENCES

[1] G. Beaucarne and A. Slaoui, “Thin film polycrystalline silicon solar cells,” Thin Film Solar Cells, Eds. J. Poortmans and V. Arkhipov, John Wiley & Sons, Ltd, pp. 97-131, 2006.
[2] B. Keyes, “National Solar Technology Roadmap: Film-Silicon PV,” Department of Energy, 2007.
[3] J. Poortmans and V. Arkhipov, Eds. “P.1 Status of photovoltaics and the role of thin film solar cells,” Thin Film Solar Cells, John Wiley & Sons, Ltd, pp. xxii, 2006.
[4] M. Zou, L. Cai, and W. D. Brown, “Fabrication of large grain polycrystalline silicon film by nano aluminum-induced crystallization of amorphous silicon,” U.S. Pat. No. 7,687,334 B2, Mar. 30, 2010.
[5] M. A. Albarghouti, H. H. Abu-Safe, H. A. Naseem, W. D. Brown, M. M. Al-Jassim, and K. M. Jones, “Large grain poly-si thin films by metal induced crystallization of α-Si:H,” 2005 Photovoltaics Specialists Conference, Conference Record of the Thirty-first IEEE, pp. 1070-1073, 2005.
[6] L. Cai, H. Wang, W. Brown, and M. Zou, “Large grain polycrystalline silicon film produced by nano-aluminum-enhanced crystallization of amorphous silicon,” Electrochemical and Solid-State Letters, vol. 8, no. 7, pp. G179-G181, 2005.
[7] M. Albarghouti, “Large grain poly-si thin films by metal-induced crystallization of a-Si:H,” Ph.D. Dissertation, University of Arkansas, Fayetteville, Ark., U.S.A., 2004.
[8] M. Imaizumi, T. Ito, M. Yamaguchi, “Effect of grain size and dislocation density on the performance of thin film polycrystalline solar cells,” Journal of Applied Physics, vol. 81, no. 11, pp. 7635-7640, 1997.
[9] J. Jang, “Super-grain poly-si by metal induced crystallization of amorphous silicon,” Solid State Phenomena, vol. 93, pp. 199-206, 2003.
[10] M. A. Green, P. A. Basore, N. Chang, D. Clugston, R. Egan, R. Evans, D. Hogg, S. Jarnason, M. Keevers, P. Lasswell, J. O'Sullivan, U. Schubert, A. Turner, S. R. Wenham, and T. Young, “Crystalline silicon on glass (CSG) thin-film solar cell modules,” Solar Energy, vol. 77, pp. 857-863, 2004.
[11] W. ChengLong, F. DuoWang, W. ChengBin, G. ZhongRong, M. A. HaiLin, and M. ShuFan, “Poly-si films with low aluminum dopant containing by aluminum-induced crystallization,” Science China: Physics, Mechanics, and Astronomy, vol. 53, no. 1, pp. 111-115, 2010.
[12] P. I. widenborg, A. G. Aberle, “Hydrogen-induced dopant neutralization in p-type AIC poly-Si seed layers functioning as buried emitters in ALICE thin-film solar cells on glass,” Journal of Crystal Growth, vol. 306, pp. 177-186, 2007.
[13] H. Zhi-Hua, L. Xian-Bo, L. Zu-Ming, X. Chao-Feng, and C. Ting-Jin, “Hydrogen passivation of multi-crystalline silicon solar cells,” Chinese Physics, vol. 12, no. 1, pp. 112-115, 2003.
[14] T. Aoyama, K. Suzuki, H. Tashiro, Y. Tada, Y. Kataoka, H. Arimoto, and K. Horiuchi, “Hydrogen-enhanced boron penetration in PMOS Devices during SiO₂ Chemical Vapor Deposition,” Japanese Journal of Applied Physics, vol. 38, pp. 2381-2384, 1999.
[15] D. Van Gestel, M. J. Romero, I. Gordon, L. Camel, J. D'Haen, G. Beaucarne, M. Al-Jassim, and J. Poortmans, “Electrical activity of intragrain defects in polycrystalline silicon layers obtained by aluminum-induced crystallization and epitaxy,” Applied Physics Letters, vol. 90, pp. 092103-1-3, 2007.
[16] Y. Matsumoto and Z. Yu, “P-type polycrystalline si films prepared by aluminum induced crystallization and doping method,” Japanese Journal of Applied Physics, vol. 40, pp. 2110-2114, 2001.
[17] D. Y. Kim, M. Gowtham, M. S. Shim, J. Yi, “Polycrystalline silicon thin film made by metal-induced crystallization,” Materials Science in Semiconductor Processing, vol. 7, pp. 433-437, 2004.
[18] J. I. Pankove, D. E. Carlson, J. E. Berkeyheiser, and R. O. Wance, “Neutralization of shallow acceptor levels in silicon and atomic hydrogen,” Physical Review Letters, vol. 51, no. 24, pp. 2224-2225, 1983.

What is claimed is:

1. A method for forming a polycrystalline film on a substrate, comprising the steps of:
forming an amorphous film having a plurality of layers on a substrate, the plurality of layers including at least a first layer formed in a first environment and a second layer formed in a second, different environment;
forming a metal layer on the amorphous film to form a structure having the substrate, the metal layer, and the amorphous film positioned between the substrate and the metal layer; and
annealing the structure at an annealing temperature for a predetermined period of time to at least partially crystallize the plurality of layers of the amorphous film simultaneously.

2. The method of claim 1, wherein the plurality of layers of the amorphous film are formed in one continuous step.

3. The method of claim 2, wherein the first environment is dynamically changed to the second environment during the continuous step of forming the amorphous film.

4. The method of claim 2, wherein the amorphous film is formed in one continuous step of sputtering or chemical vapor deposition.

5. The method of claim 1, wherein the first environment comprises diborane.

6. The method of claim 1, wherein the second environment comprises phosphine.

7. The method of claim 1, wherein the amorphous film is formed to have a thickness within a range from about 0.1 μm to about 40 μm.

8. The method of claim 1, wherein the amorphous film is formed at a pressure of about 10⁻⁶ torr.

9. The method of claim 1, wherein the amorphous film comprises at least one of amorphous silicon, germanium, and silicon carbide.

10. The method of claim 1, wherein the metal layer is formed to have a thickness in a range from about 5 nm to about 300 nm.

11. The method of claim 1, wherein the metal layer is formed by sputtering or thermal evaporation.

12. The method of claim 1, wherein the metal layer is formed at a pressure of about 10⁻⁸ torr.

13. The method of claim 1, wherein the metal layer comprises aluminum.

14. The method of claim 1, wherein the step of annealing the structure comprises at least one of raising, maintaining, and lowering the annealing temperature during the predetermined period of time.

15. The method of claim 1, wherein the annealing temperature is within a range from about 150° C. to about 550° C.

16. The method of claim 1, wherein the step of annealing the structure comprises annealing the structure in an annealing environment comprising hydrogen or argon.

17. The method of claim 1, wherein the first environment and the second environment are adapted such that the amorphous film is formed to be at least partially hydrogenated.

18. The method of claim 1, wherein the predetermined period of time is within a range from about 15 minutes to about 20 hours.

19. The method of claim 1, wherein the substrate is heated to about 200° C.

20. The method of claim 1, wherein the step of forming an amorphous film further comprises forming a third layer in a third environment that is different from the first environment and the second environment.

21. The method of claim 20, wherein forming the amorphous silicon film comprising the first layer, second layer, and third layer is performed in one continuous step.

22. The method of claim 21, wherein the first environment is dynamically changed to the second environment and the second environment is dynamically changed to the third environment during the step of forming the amorphous film.

23. The method of claim 20, wherein the third environment comprises silane.

24. The method of claim 1, wherein the metal layer has a thickness that is about the same as the thickness of the amorphous silicon film.

25. A polycrystalline film formed by the method of claim 1.

26. A method for forming a polycrystalline silicon film on a substrate, comprising the steps of:
forming an amorphous silicon film having a plurality of layers on a substrate, the plurality of layers including at least a first layer formed in a first environment and a second layer formed in a second, different environment;
forming an aluminum layer on the amorphous silicon film to form a structure having the substrate, the aluminum layer, and the amorphous silicon film positioned between the substrate and the aluminum layer; and
annealing the structure at an annealing temperature for a predetermined period of time to at least partially crystallize the plurality of layers of the amorphous silicon film simultaneously.

27. The method of claim 26, wherein the first layer, second layer, and third layer are formed in one continuous step.

28. The method of claim 27, wherein the first environment is dynamically changed to the second environment during the continuous step of forming the amorphous silicon film.

29. The method of claim 26, wherein the first environment comprises diborane.

30. The method of claim 26, wherein the second environment comprises phosphine.

31. The method of claim 26, wherein the amorphous silicon film is formed to have a thickness within a range from about 0.1 μm to about 40 μm.

32. The method of claim 26, wherein the amorphous silicon film is formed by sputtering or chemical vapor deposition.

33. The method of claim 26, wherein the amorphous silicon film is formed by plasma-enhanced chemical vapor deposition at a pressure of about 10⁻⁶ torr.

34. The method of claim 26, wherein the aluminum layer is formed to have a thickness in a range from about 5 nm to about 300 nm.

35. The method of claim 26, wherein the aluminum layer is formed by sputtering or thermal evaporation.

36. The method of claim 26, wherein the aluminum layer is formed by sputtering at a pressure of about 10⁻⁸ torr.

37. The method of claim 26, wherein annealing the structure comprises at least one of raising, maintaining, and lowering the annealing temperature during the predetermined period of time.

38. The method of claim 26, wherein the annealing temperature is within a range from about 150° C. to about 550° C.

39. The method of claim 26, wherein annealing the structure comprises annealing the structure in an annealing environment comprising hydrogen or argon.

40. The method of claim 26, wherein the predetermined period of time is within a range from about 15 minutes to about 20 hours.

41. The method of claim 26, wherein the first environment and the second environment are adapted such that the amorphous silicon film is formed at least partially of hydrogenated amorphous silicon.

42. The method of claim 26, wherein the substrate is heated to about 200° C.

43. The method of claim 26, wherein the step of forming an amorphous silicon film further comprises forming a third layer in a third environment that is different from the first environment and the second environment.

44. The method of claim 43, wherein the first layer, second layer, and third layer are formed in one continuous step.

45. The method of claim 44, wherein the first environment is dynamically changed to the second environment and the second environment is dynamically changed to the third environment during the continuous step of forming the amorphous silicon film.

46. The method of claim 43, wherein the third environment comprises silane.

47. The method of claim 26, wherein the metal layer has a thickness that is about the same as the thickness of the amorphous silicon film.

48. A polycrystalline silicon film formed by the method of claim 26.

49. An apparatus for forming a polycrystalline film, comprising:
a film forming system configured to form an amorphous film having a plurality of layers on a substrate, the plurality of layers including at least a first layer formed in a first environment and a second layer formed in a second, different environment;
a metal layer forming system configured to form a metal layer on the amorphous film to form a structure having the substrate, the metal layer, and the amorphous film positioned between the substrate and the metal layer; and
an annealing means configured to anneal the structure at an annealing temperature for a predetermined period of time to at least partially crystallize the plurality of layers of the amorphous film simultaneously.

50. The apparatus of claim 49, wherein the first layer and second layer of the amorphous film are formed in one continuous step.

51. The apparatus of claim 50, wherein the first environment is dynamically changed to the second environment during the continuous step of forming the amorphous film.

52. The apparatus of claim 49, wherein the film forming system, metal layer forming system, and annealing means are configured such that the functions of forming the amorphous film, forming the metal layer, and annealing the structure are performed as a continuous process and in a sequential order.

53. The apparatus of claim 50, wherein the first environment comprises diborane.

54. The apparatus of claim 50, wherein the second environment comprises phosphine.

55. The apparatus of claim 49, wherein the film forming system is further configured to form the amorphous film to include a third layer in a third environment that is different from the first environment and the second environment.

56. The apparatus of claim 55, wherein the first layer, second layer, and third layer of the amorphous film are formed in one continuous step.

57. The apparatus of claim 56, wherein the first environment is dynamically changed to the second environment and the second environment is dynamically changed to the third environment during the continuous step of forming the amorphous film.

58. The apparatus of claim 54, wherein the third environment comprises silane.

59. The apparatus of claim 49, wherein the film forming system comprises one of a chemical vapor deposition system, electron cyclotron resonance system, electron beam physical vapor deposition system, and sputtering system.

60. The apparatus of claim 59, wherein the film forming system comprises one of a plasma-enhanced chemical vapor deposition (PECVD) system, low-pressure chemical vapor deposition (LPCVD) system, and hot wire chemical vapor deposition system.

61. The apparatus of claim 49, wherein the film forming system is configured to form the amorphous film to have a thickness within a range from about 0.1 μm to about 40 μm.

62. The apparatus of claim 49, wherein the amorphous film comprises at least one of amorphous silicon, germanium, and silicon carbide.

63. The apparatus of claim 49, wherein the film forming system is configured to form the amorphous film at a pressure of about 10⁻⁶ torr.

64. The apparatus of claim 49, wherein the metal layer forming system comprises a sputtering system or a thermal evaporation system.

65. The apparatus of claim 49, wherein the metal layer forming system is configured to form the metal layer to have a thickness in a range from about 5 nm to about 300 nm.

66. The apparatus of claim 49, wherein the metal layer forming system is configured to form the metal layer at a pressure of about 10⁻⁸ torr.

67. The apparatus of claim 49, wherein the metal layer comprises aluminum.

68. The apparatus of claim 49, wherein annealing means is configured to selectively cause the annealing temperature to be at least one of raised, maintained, and lowered during the predetermined period of time.

69. The apparatus of claim 49, wherein the annealing temperature is within a range from about 150° C. to about 550° C.

70. The apparatus of claim 49, wherein the annealing means is configured to anneal the structure in an annealing environment comprising hydrogen or argon.

71. The apparatus of claim 49, wherein the first environment and the second environment are adapted such that the amorphous film is formed to be at least partially hydrogenated.

72. The apparatus of claim 49, wherein the predetermined period of time is within a range from about 15 minutes to about 20 hours.

73. The apparatus of claim 49, wherein the substrate is heated to about 200° C.

74. The apparatus of claim 49, wherein the thickness of the metal layer is about the same as the thickness of the amorphous film.
